(19) United States
(12) Patent Application Publication
(10) Pub. No.: US 2008/0001233 A1
(43) Pub. Date: Jan. 3, 2008

(54) Semiconductor device with circuits formed with essentially uniform pattern density

(76) Inventors: Ashok Kumar Kapoor, Palo Alto, CA (US); Richard K. Chou, Palo Alto, CA (US); Damodar R. Thummalapally, Milpitas, CA (US)

Correspondence Address: WALKER & SAKO, LLP, Suite 235, 300 South First Street, San Jose, CA, 95113, US

(21) Appl. No.: 11/540,830

(22) Filed: Sep. 28, 2006

Related U.S. Application Data
(63) Continuation-in-part of application No. 11/452,442, filed on Jun. 13, 2006.
(60) Provisional application No. 60/799,787, filed on May 11, 2006.

(51) Int. Cl. H01L 29/94

(52) U.S. Cl. 257/369

(57) ABSTRACT

A semiconductor device can include a first circuit section having at least one transistor coupled to at least three conductive lines formed from a conductive layer. No more than one of the at least one of the three conductive lines forms a control terminal of the at least one transistor. In addition, a second circuit section includes at least two transistors. Each such transistor can have a control terminal formed by a conductive line formed from the same conductive layer. The three conductive lines of the first circuit section can have the same pitch pattern as the conductive lines of the second circuit section.

This application is a continuation-in-part of U.S. patent application Ser. No. 11/452,442 filed on Jun. 13, 2006, which claims the benefit of U.S. Provisional Patent Application Ser. No. 60/799,787 filed on May 11, 2006. The contents of both of these applications are incorporated by reference herein.

### TECHNICAL FIELD

The present invention relates generally to semiconductor devices, and more particularly to semiconductor devices having logic gates.

### BACKGROUND OF THE INVENTION

Non-uniform pattern density in interconnecting layers in semiconductor devices has become an increasingly problematic issue in the manufacturing of semiconductor devices. Forming small feature sizes using photolithography at small wavelengths (i.e., 65 nm) can be problematic when pattern density varies. This may be caused by optical proximity effects that can vary among different features sizes, shapes, and/or differing pattern densities. Various optical proximity correction (OPC) techniques have been used to compensate for such adverse effects with varying degrees of success.

Another problematic manufacturing issue caused by non-uniform pattern density across a semiconductor device can arise during a chemical mechanical polishing (CMP) step. A more sparsely patterned area can be polished at a faster rate than a more densely patterned area. Consequently, a polished surface can have a lower surface level in a sparsely patterned area resulting in “dishing”. Dishing can be caused by features in densely patterned areas sharing the load of the CMP with neighbors, while more isolated features receive more of the load of the CMP. That is, dishing is the result of the more sparsely patterned area being over polished. At times the polish stopper layer may be completely polished away and the patterned feature may be too thin in a sparsely patterned area.

Further, a resulting uneven topology resulting from dipping may create additional problems in subsequent process steps.

Differing pattern density may also affect etch rates. For example, a more densely pattern area may have a different etch rate than a more sparsely patterned area. This can particularly affect features having a small size.

Conventional logic gates can have differing pattern densities based on the logic function being performed. As examples, conventional layouts of an inverter and a four input NAND function will now be considered.

Referring now to FIGS. 1A and 1B, a top plan view of transistor structures used in conventional logic gates are illustrated having different gate pattern densities. FIG. 1A is a top plan view of a single transistor 100A that may be used in an inverter circuit. FIG. 1B is a top plan view of a series of four transistors that can be used in a four input NAND circuit and given the general reference character 100B.

Single transistor 100A includes a gate 110, a source contact 120 and a drain contact 130. Gate 110 is a polysilicon layer separated from a substrate surface by a gate insulator, source and drain contacts (120 and 130) are metal contacts used to connect source and drain regions to a metal interconnect layer (not shown) formed above the polysilicon layer forming gate 110. A single transistor 100A can be an n-channel MOS transistor in a CMOS inverter circuit, as but one example.

Four series connected transistors 100B include gates (140, 150, 160, and 170), and contacts (180 and 190). Series connected transistors 100B can be n-channel transistors forming a pull-down path in a four input CMOS NAND gate, as but one example.

Conventionally, polysilicon is typically a first conductive layer formed above a substrate of a semiconductor device, and is used to form an insulated control gate. As shown in FIGS. 1A and 1B, a pattern density of polysilicon for the four series connected transistors 100B can be much greater than the pattern density of single transistor 100A. As noted above, such differences in pattern density can cause problems such as variations in pattern shapes due to optical proximity effects, dishing in later process steps, such as a CMP step, or other problems in the manufacturing of a device.

### BRIEF DESCRIPTION OF THE DRAWINGS

FIGS. 1A and 1B are top plan views and schematic diagrams of transistor structures used in conventional logic gates having different gate pattern densities.

FIGS. 2A and 2B are top plan views of transistor structures according to an embodiment.

FIG. 3A is a circuit schematic diagram for the single transistor structure of FIG. 2A for an insulated gate field effect transistor (IGFET) embodiment. FIG. 3B is a circuit schematic diagram of the series transistor structure of FIG. 2B for an insulated gate field effect transistor (IGFET) embodiment.

FIG. 4A is a circuit schematic diagram for the single transistor structure of FIG. 2A for a junction field effect transistor (JFET) embodiment. FIG. 3B is a circuit schematic diagram of the series transistor structure of FIG. 2B for a junction gate field effect transistor (JFET) embodiment.

FIG. 5A is cross-sectional diagram of the single transistor structure of FIG. 2A for an IGFET embodiment. FIG. 5B is cross-sectional diagram of the series transistor structure of FIG. 2B for an IGFET embodiment.

FIG. 6A is cross-sectional diagram of the single transistor structure of FIG. 2A for a JFET embodiment. FIG. 6B is cross-sectional diagram of the series transistor structure of FIG. 2B for a JFET embodiment.

FIGS. 7A to 7C show steps for making transistor structures according to an embodiment.

FIGS. 8A to 8E show additional steps for making transistor structures according to an embodiment.

FIGS. 9A to 9E show additional steps for making transistor structures according to an embodiment.

FIGS. 10A to 10C additional steps for making transistor structures according to an embodiment.

FIG. 11 is an example of a first mask pattern for forming first edges of conductive lines according to an embodiment.

FIG. 12 is an example of a second mask for forming second edges of conductive lines according to an embodiment.

FIG. 13 is a top plan view of conductive lines formed with the mask patterns of FIGS. 11 and 12.

FIG. 14 is a block schematic diagram of a circuit that can be formed according to an embodiment.

FIG. 15A is an example of a second mask for forming second edges of conductive lines according to an embodiment.

FIG. 15B is a top plan view of conductive lines formed with the mask patterns of FIGS. 11 and 15A.

FIGS. 16A and 16B are top plan views of transistors structures according to another embodiment.

FIGS. 17A and 17B are top plan views of transistors structures according to another embodiment.

FIGS. 18A and 18B show a conventional source/drain contact formation step.

FIGS. 19A to 19E show a contact formation step according to an embodiment.

FIG. 20 shows a transistor structure according to another embodiment.

FIG. 21 is a top plan view of a conventional device isolation arrangement.

FIG. 22 is a top plan view of an isolation arrangement according to an embodiment.

FIG. 23A is a top plan view of a particular transistor structure according to an embodiment. FIG. 23B is a top plan view of a particular transistor structure according to another embodiment FIG. 24 is a top plan view showing a layer doping step for the embodiment of FIG. 23A.

FIG. 25 is a top plan view showing variable gate width arrangement according to an embodiment.

FIGS. 26A to 26E are side cross sectional views showing the formation of JFET and IGFET devices in a same substrate according to an embodiment.

### DETAILED DESCRIPTION OF THE EMBODIMENTS

Various embodiments of the present invention will now be described in detail with reference to a number of drawings. The embodiments show circuits formed having a common interconnect layer for control terminals and terminals connected to impedance paths controlled by the control terminals. In this way, various different logic gates may be formed having essentially uniform pattern density.

Referring to FIGS. 2A and 2B, top plan views of transistor structures according to an embodiment used in various logic gates are illustrated having essentially uniform gate pattern densities. FIG. 2A is a top plan view of a single transistor structure 200A that may be used in an inverter circuit, for example. FIG. 2B is a top plan view of a series transistor structure of four transistors that can be used in a four input NAND circuit, for example, and is given the general reference character 200B.

Referring now to FIG. 2A, single transistor structure 200A can include conductive lines 202 to 214 formed over an active area 220. Conductive lines 202 to 214 may be polysilicon lines, for example, preferably polysilicon lines formed from a same deposited layer. Single transistor structure 200A may form two transistors T1 and T2 that may be IGFETs (Insulated Gate Field Effect Transistors) or JFETs (Junction Field Effect Transistors), as but two examples.

Conductive lines (202, 204, and 206) may form nodes for transistor T1. Conductive line 202 may be a drain contact. Conductive line 204 may be a gate structure. In the case of an IGFET, such a gate structure can include a gate insulator between the conductive line 204 and a substrate. In the case of a JFET, such a gate structure can form all, or a portion of a p-n junction with respect to the substrate. Conductive line 206 may be a source contact.

In a similar fashion, conductive lines (210, 212, and 214) may form nodes for transistor T2. Conductive line 210 may be a source contact. Conductive line 212 may be a gate structure. Again, in the case of an IGFET, such a gate structure can include a gate insulator between the conductive line 212 and a substrate. In the case of a JFET, such a gate structure can form all, or a portion of a p-n junction with respect to the channel. Conductive line 214 may be a drain contact.

Conductive line 208 may form a contact to a common well from both transistors T1 and T2. Transistors T1 and T2 may form individual transistors in separate logic circuits, such as an inverter, for example. By having completely independent sources, drains, and gates, transistors T1 and T2 may operate independently.

In this way, single transistors can have increased pattern density with the inclusion of conductive lines as source and/or drain contacts that are formed from a same layer as a gate.

Referring now to FIG. 2B, a series transistor structure 200B may include conductive lines 232 to 244 formed over an active area 250. Conductive lines 232 to 244 may be polysilicon lines, for example, preferably polysilicon lines formed from a same deposited layer. Series transistor structure 200B may form four transistors T3 to T6 that may be IGFETs or JFETs, as but two examples. Conductive line 232 may form a source/drain connection and conductive line 234 may form a control gate to transistor T3. Active area 250 between conductive lines 234 and 236 may form a common source/drain for both transistors T3 and T4. Conductive line 236 may form a control gate for transistor T4. Active area 250 between conductive lines 236 and 238 may form a common source/drain for both transistors T4 and T5. Conductive line 238 can form a control gate for transistor T5. Active area 250 between conductive lines 238 and 240 may form a common source/drain for both transistors T5 and T6. Conductive line 240 forms a control gate for transistor T6 and conductive line 242 can form a source/drain connection for transistor T6.

As in the case of FIG. 2A, in the example of FIG. 2B, if a control gate conductive line (any of 234, 236, 238, 240) is for an IGFET, such a gate structure can include a gate insulator between the conductive line and a substrate. On the other hand, if such a control gate is for a JFET, such a gate structure can form all, or a portion of a p-n junction with respect to the channel.

Conductive line 244 can form a well contact to provide a common back gate bias to series connected transistors T3 to T6.

As understood by comparing FIGS. 2A and 2B noted, a single transistor structure 200A that includes two transistors can have essentially the same pattern density as series transistor structure 200B that includes four transistors with respect to a conductive layer forming such structures (e.g., a first conductive layer which can be a polysilicon layer). Looked at in another way, conductive lines of the single transistor structure 200A can have the same pitch (distance between adjacent conductive lines) as conductive lines as series transistor structure 200B.

By doing so, process steps such as a photolithography step or a CMP step may be improved and hence an overall process yield may be improved.

It is noted that while conductive line patterns shown in the various embodiments may preferably be formed with a minimum achievable line width, other embodiments may include patterns with line widths larger than a minimum achievable width.

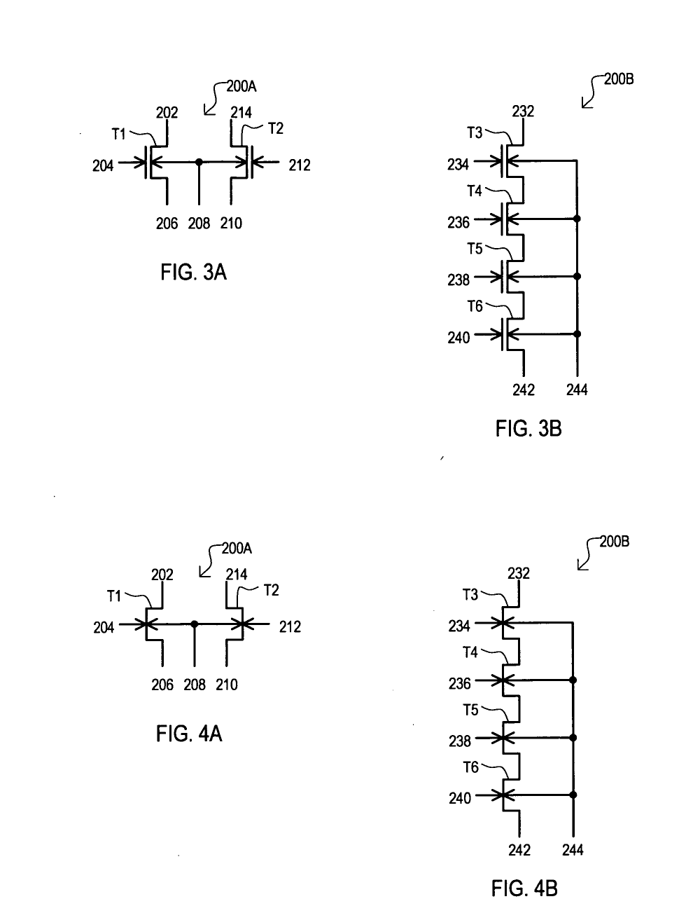

FIGS. 3A and 3B set forth a circuit schematic diagram for single transistor structure 200A and series transistor structure 200B for particular IGFET embodiments. FIGS. 3A and 3B may include similar constituents as FIGS. 2A and 2B and such constituents may be given the same reference character.

Referring now to FIG. 3A, single transistor structure 200A can include transistors T1 and T2. Transistor T1 can includes a drain terminal that can include conductive line 202, a gate terminal that can include conductive line 204, and source terminal that can include conductive line 206. Transistor T2 includes a drain terminal that can include conductive line 214, a gate terminal that can include conductive line 212, and source terminal that can include conductive line 210. Transistors T1 and T2 include a common back gate (well) terminal that includes conductive line 208. Terminals 202 to 210 in single transistor structure 200A of FIG. 3A correspond to conductive lines 202 to 210 of FIG. 2A. In FIG. 3A, transistors T1 and T2 can be IGFETs.

Referring now to FIG. 3B, a series transistor structure 200B can include series connected transistors T3 to T6. Transistor T3 includes a drain terminal that can include conductive line 232, a gate terminal that can include conductive line 234 and has a source terminal connected with a drain of transistor T4. Transistor T4 includes a gate terminal that can include conductive line 236 and has a source connected with a drain of transistor T5. Transistor T5 includes a gate terminal that can include conductive line 238 and has a source connected with a drain of transistor T6. Transistor T6 has a gate terminal that can include conductive line 240 and a source terminal that can include conductive line 242. Transistors T3 to T6 have a common back gate terminal that can include conductive line 244. Terminals 232 to 244 of series connected transistors 200B FIG. 3B correspond to conductive lines 232 to 244 of FIG. 2B. In FIG. 3B, transistors T1 to T4 are IGFETs.

In this way, IGFET transistors (e.g., MOS transistors) can be formed in structures with essentially uniform pattern density, while at the same time providing different device densities.

While an approach like that shown in FIGS. 2A and 2B can be utilized to form IGFET circuits, in alternate embodiments JFET circuits can be formed. Two particular examples of such JFET circuits are shown in FIGS. 4A and 4B.

FIGS. 4A and 4B set forth a circuit schematic diagram for single transistor structure 200A and series transistor structure 200B for a JFET embodiment. FIGS. 4A and 4B may include similar constituents as FIGS. 2A and 2B and such constituents may be given the same reference character.

Referring now to FIG. 4A, single transistor structure 200A includes transistors T1 and T2. Transistor T1 includes a drain terminal that includes conductive line 202, a gate terminal that includes conductive line 204, and a source terminal that includes conductive line 206. Transistor T2 includes a drain terminal that includes conductive line 214, a gate terminal that includes conductive line 212, and a source terminal that includes conductive line 210. Transistors T1 and T2 include a common back gate (well) terminal that includes conductive line 208. Terminals 202 to 210 in single transistor structure 200A of FIG. 4A correspond to conductive lines 202 to 210 of FIG. 2A. In FIG. 4A, transistors T1 and T2 are JFETs.

Referring now to FIG. 4B, series transistor structure 200B includes series connected transistors T3 to T6. Transistor T3 includes a drain terminal that includes conductive line 232, a gate terminal that includes conductive line 234 and has a source connected with a drain of transistor T4. Transistor T4 includes a gate terminal that includes conductive line 236 and has a source connected with a drain of transistor T5. Transistor T5 includes a gate terminal that includes conductive line 238 and has a source connected with a drain of transistor T6. Transistor T6 has a gate terminal that includes conductive line 240 and a source terminal 242. Transistors T3 to T6 have a common back gate terminal that includes conductive line 244. Terminals 232 to 244 of series connected transistors 200B FIG. 3B correspond to conductive lines 232 to 244 of FIG. 2B. In FIG. 4B, transistors T3 to T6 are JFETs.

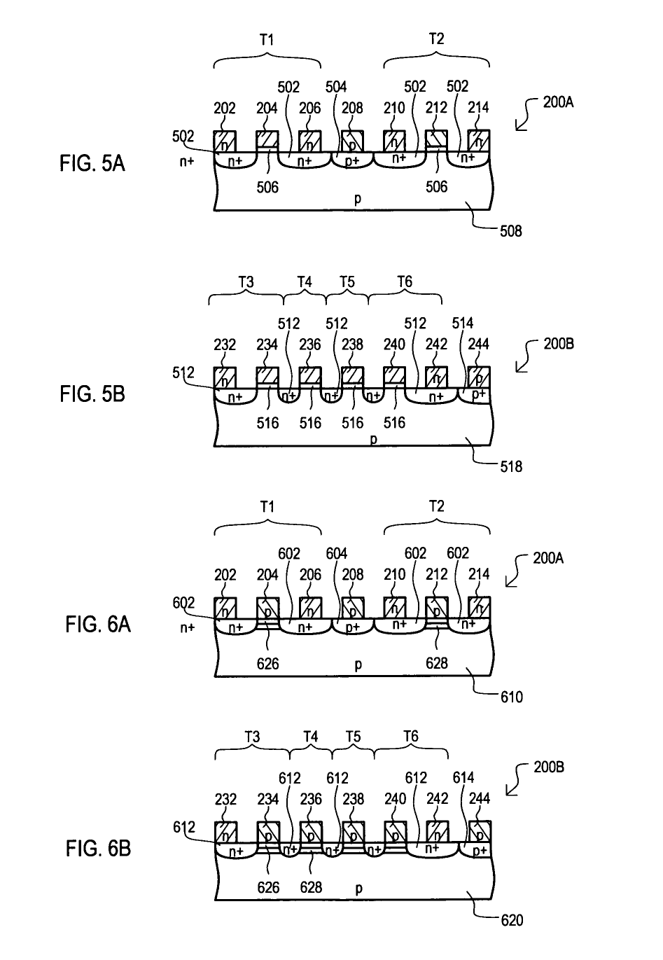

Referring now to FIG. 5A, an IGFET embodiment of the single transistor structure 200A of FIG. 2A is shown in a cross sectional view. The cross sectional view is taken along line I-I of FIG. 2A.

In the example of FIG. 5A, source/drains 502 can be formed by implanting a substrate region 508 (e.g., a well region) with impurities. In the particular example shown, source/drains 502 are n+ regions, and thus can be formed by implanting phosphorous and/or arsenic into a p-type substrate 508. However, p-type source/drains could be formed by implanting boron into an n-type substrate. Conductive lines 202 and 206 can each provide a contact to respective source/drains for transistor T1. Conductive line 204 can provide a gate terminal for transistor T1, thus a gate insulating layer 506 can be included between conductive line 204 and a channel formed between source/drains 502 of transistor T1. In a similar fashion, conductive lines 210 and 214 can each provide a contact to respective source/drains for transistor T2. Conductive line 212 provides a gate terminal for transistor T2, thus can include gate insulating layer 506 between conductive line 212 and a channel formed between source/drains 502 of transistor T2.

A contact region 504 may be formed by implanting impurities into substrate region 508 of the same conductivity type as the substrate region. Thus, in the example of FIG. 5A, contact region 504 can be formed by implanting an impurity, such as boron for example, to form a p+ doped region. Of course, in a p-channel case, a substrate region 508 can be n-type and a contact region 504 can be formed by implanting an n-type dopant.

Referring still to FIG. 5A, conductive lines 202, 206, 210, and 214 may be n-doped polysilicon to provide contacts to source/drains 502. Conductive line 208 may be p-doped polysilicon to provide a contact to well 508 through p+ contact region 504. In this way, an individual transistor structure 200A having individual IGFET transistors T1 and T2 may be formed.

Referring now to FIG. 5B, an IGFET embodiment of the series transistor structure 200B of FIG. 2B is shown in a cross sectional view. The cross sectional view is taken along line II-II of FIG. 2B.

Referring now to FIG. 5B, source/drains 512 can formed by implanting a substrate region 518 with impurities (such as phosphorous and/or arsenic to provide an n+ type doping or boron to provide a p+ type doping). Conductive line 232 can provide a contact to a respective source/drain 512 of transistor T3. Conductive lines 234, 236, 238, and 240 can provide gate terminals for transistors T3, T4, T5 and T6, respectively. Because such transistors are IGFET type transistors, gate insulating layers 516 can be included between the conductive lines (234 236, 238, and 240) and a channel formed between source/drains of the transistor (T3, T4, T5 and T6). Conductive line 242 can provide a contact to a source/drain 512 for transistor T6.

A contact region 514 may be formed like contact region 504 of FIG. 5A.

Referring now to FIG. 6A, a JFET embodiment of the single transistor structure 200A of FIG. 2A is shown in a cross sectional view. The cross sectional view is taken along line I-I of FIG. 2A. FIG. 6A can include similar constituents as FIGS. 5A and 2A, thus like constituents may be given the same reference character.

FIG. 6A can differ from FIG. 5A in that channels of transistor T1 and T2 can include gate diffused regions 626 and channel regions 628. Gate diffused regions 626 can be formed by the out-diffusion from control gates. Thus, in the example shown, gate diffused regions can be formed from p-type dopants. Channel regions 628 can be formed below gate diffused regions 626, and can be of the same conductivity type as source/drain regions 602. Thus, in the example of FIG. 6A, channel regions 628 can be n-type regions.

In this way, an individual transistor structure 200A having individual JFET transistors T1 and T2 may be formed.

Referring now to FIG. 6B, a JFET embodiment of the series transistor structure 200B of FIG. 2B is shown in a cross sectional view. The cross sectional view is taken along line II-II of FIG. 2B. FIG. 6B can include similar constituents as FIGS. 5B and 2B, thus like constituents may be given the same reference character.

Like FIG. 6A, FIG. 6b can differ from FIG. 5B in that channels of transistor T3 to T6 can each include a gate diffused region 626 and channel region 628 (shown only for transistor T3 in FIG. 6B).

In this way, a series transistor structure 200B having series connected transistors T3 to T6 may be formed.

From FIGS. 5A and 5B, it is understood that various logic circuits, such as gates, can be formed from IGFETs on a semiconductor device having essentially uniform pattern density. That is, transistor structures can be formed according to such figures by forming transistor as needed for a circuit, with series connected transistors of the same conductivity type arranged as in FIG. 5B, and single or parallel transistors being connected as in FIG. 5A.

Similarly, FIGS. 6A and 6B illustrate that various logic gates may be formed from JFETs on a semiconductor device having essentially uniform pattern density, according to the same approach.

In the particular embodiments of FIGS. 5A, 5B, 6A, and 6B an individual transistor structure 200A and a series transistor structure 200B examples are used to illustrate how either series or parallel transistor structures may be formed having essentially uniform pattern density. In this way, any logic gate combination may be formed using the techniques illustrated herein with each individual logic gate having essentially a uniform pattern density with the other individual logic gates. By doing so, a semiconductor device having a variety of different logic gates may be formed while keeping an essentially uniform pattern density throughout.

Series transistor structure 200B is shown to include four transistors T3 to T6, however, any number of transistors may be connected in series and having essentially uniform pattern density as any other number of transistors according to the embodiments. In the embodiments as described above, any number of transistors may be connected in series or parallel while maintaining an essentially uniform pattern density throughout a semiconductor device.

Individual transistor structure 200A and series transistor structure 200B are illustrated with n-channel IGFETs and n-channel JFETs, however as noted above, it is understood that conductivities may be reversed to form p-channel IGFETs and/or p-channel JFETs. As a result complementary logic can be formed on a semiconductor chip while maintaining essentially uniform pattern density.

Another feature of the embodiments is that by using conductive lines (202 to 214 and 232 to 244) to form gates and source, drain, and well contacts to transistors, structure height of all lines providing connection to sources, drains, and wells and providing gate structures may be essentially uniform.

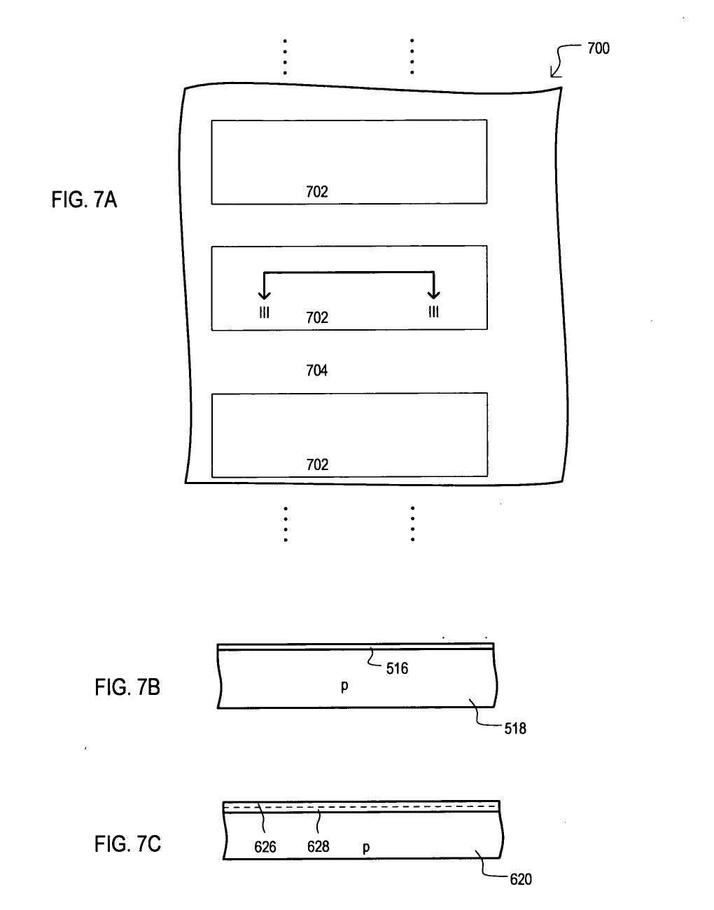

Referring now to FIGS. 7A to 10B, a method of forming various circuits, such as logic gates, including conductive lines having essentially uniform pattern density and small device features (i.e., 65 nm and less) will be described in a series of top plan views and corresponding side cross sectional views.

Referring now to FIG. 7A a circuit area is shown in a top plan view and designated by the general reference character 700. FIG. 7B shows a cross section view along line III-III of FIG. 7A for an IGFET embodiment. FIG. 7C shows a cross section view along line III-III of FIG. 7A for a JFET embodiment. As shown in FIG. 7A, various active areas 702 can be formed that are separated from one another by isolation regions 704, such as shallow trench isolation (STI), as but one example.

As shown in FIG. 7B, in an IGFET embodiment, a gate insulator 516 can be formed. In addition, active area could be subject to threshold voltage implantation steps prior to a gate insulator forming step.

As shown in FIG. 7C, in a JFET embodiment, a channel region 628 may be started by an implantation step. That is, channel dopants may be implanted into the substrate that can form JFET channels taking into account subsequent heat cycles in the manufacturing process. Optionally, in some embodiments, a gate diffused region 626 may also be started by ion implantation or other diffusion steps. However, preferably gate diffused regions can be formed by out-diffusion from control gates.

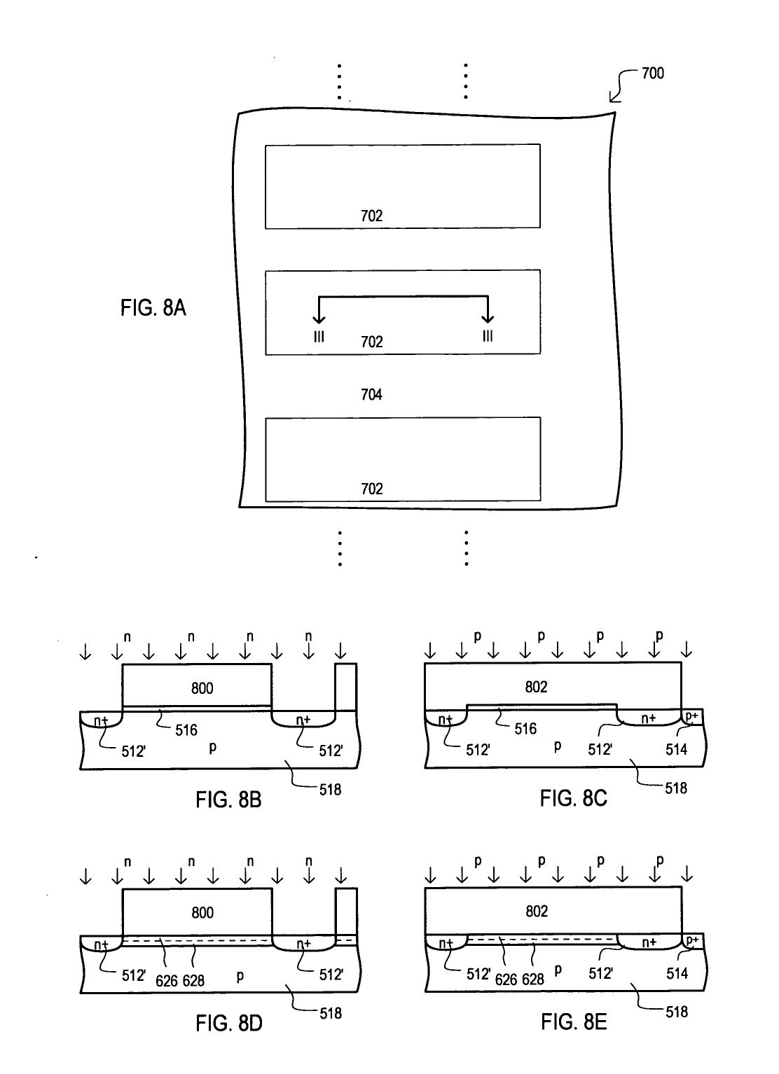

Referring now to FIGS. 8A to 8D, contact regions can be formed in active areas 702 for subsequent connection to first layer conductive lines.

FIGS. 8B and 8C show an IGFET embodiment. FIGS. 8D and 8E show a JFET embodiment. As shown by FIGS. 8B and 8C, a gate insulator 516 can be removed from contact regions.

In the examples shown, contact region formation steps can be the same for both IGFET and JFET embodiments. As shown in FIGS. 8B and 8D, first conductivity type contact regions 512′ can be formed with a ion implantation step having a mask 800 that exposes only locations of first type contact region 512′. In the particular example shown, such regions can be n+ contact regions. As shown in FIGS. 8C and 8E, second conductivity type contact regions 514 can be formed with an ion implantation step utilizing a mask 802 that exposes only locations for second type contract regions 514. In the particular example shown, such regions can be p+ contact regions.

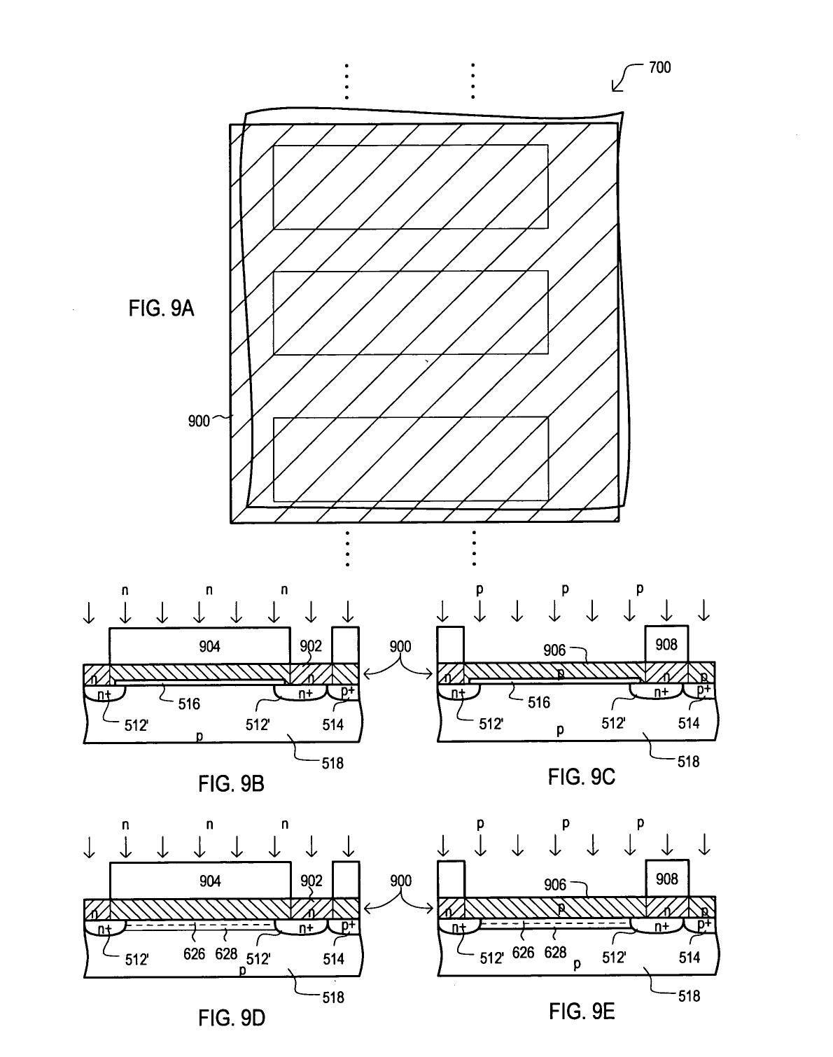

Referring now to FIGS. 9A to 9E, a first conductive layer can be formed and given appropriate doping for different conductive lines.

A conductive layer 900 can be formed over substrate 518. Preferably such a layer is polysilicon. Optionally, such a conductive layer 900 step can provide doping in situ. Alternatively, conductive layer 900 can be blanket doped to a particular conductivity type.

In the examples shown, gate doping steps can be the same for both IGFET and JFET embodiments. As shown in FIGS. 9B and 9D, first conductivity line regions 904 can be formed with a ion implantation step that implants dopants into conductive layer 900. Such a step can use a mask 904 that exposes only locations of conductive lines of a first conductivity type. In the particular example shown, such regions can be n+ line regions. As shown in FIGS. 9C and 9E, second conductivity line regions 906 can be formed with an ion implantation step that implants different type dopants into conductive layer 900. Such a step can use a mask 908 that exposes only locations of conductive lines of a second conductivity type. In the particular example shown, such regions can be p+ line regions.

It is understood that if a conductive layer 900 is initially blanket doped, one of the particular doping steps shown by FIGS. 9B/9C or FIGS. 9D/9E can be omitted.

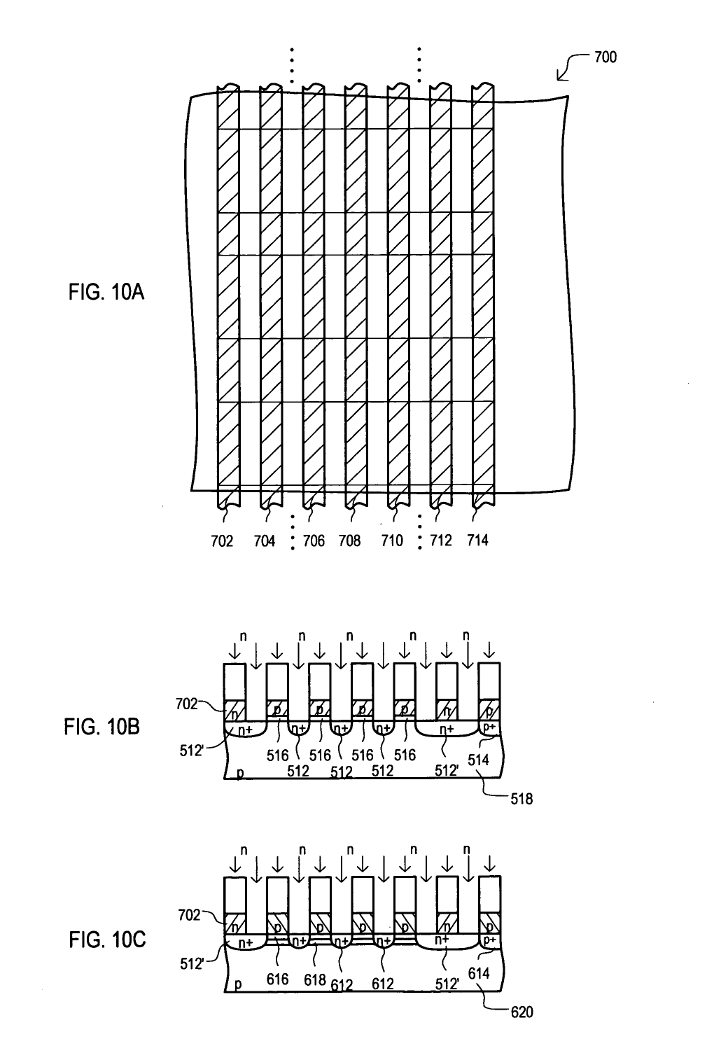

Referring now to FIGS. 10A to 10C, a first conductive layer can be etched to form conductive lines having a uniform density. In addition, adjacent source/drain regions can be formed with an ion implantation step.

A conductive layer can be etched to form conductive lines 702 to 714. Preferably, a same etch mask used to form such conductive lines may also be used as an implantation mask, as shown in FIGS. 10B and 10C. Such an arrangement can form self-aligned source/drain regions.

In this way, circuits having essentially uniform pattern density can be formed that include IGFETs, JFETs or some combination thereof.

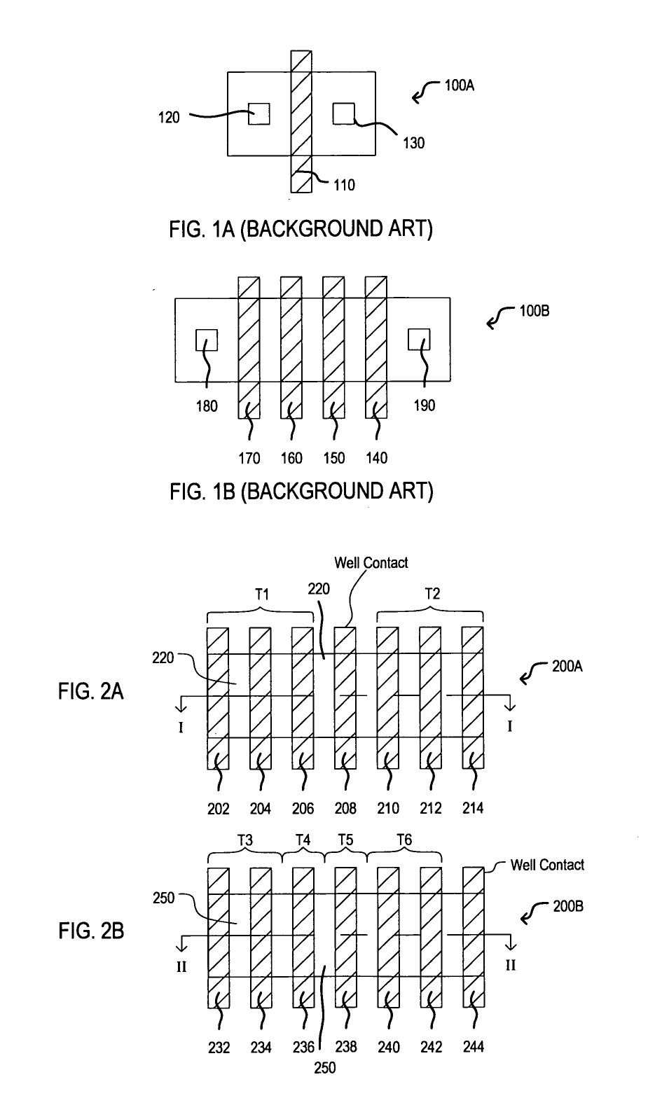

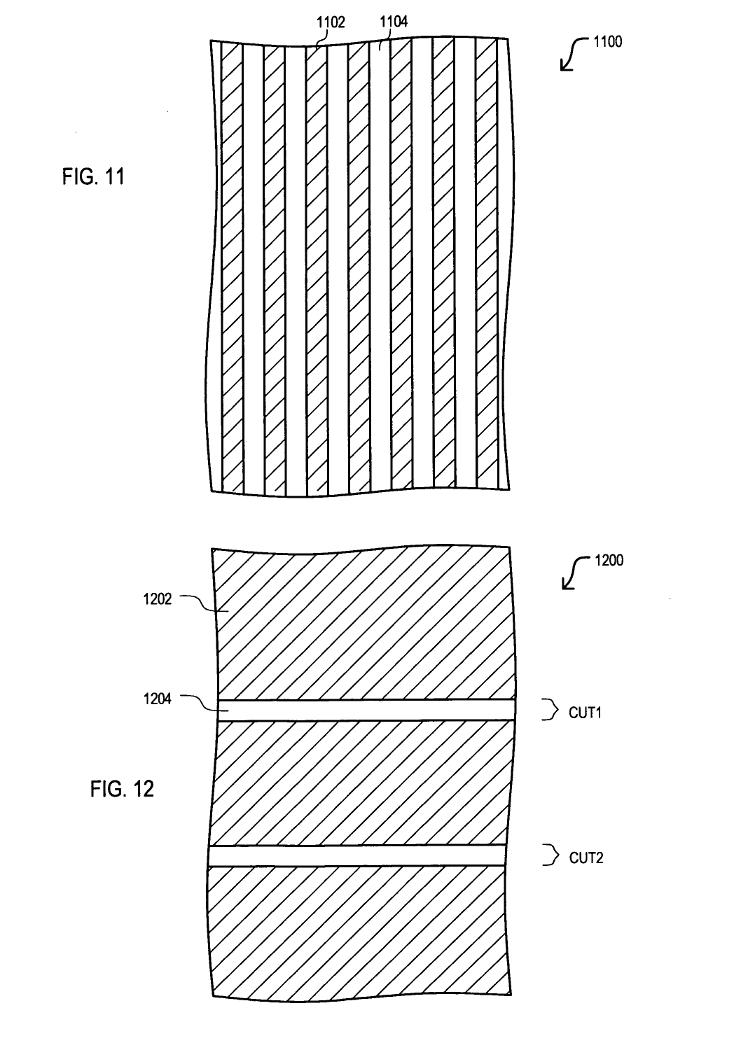

FIG. 10A also shows an arrangement in which conductive lines can be formed in one direction (vertical in FIG. 1A), with each conductive line being a contiguous structure. It is understood that such lines can be subsequently divided by a later etching step. An example of such an approach is shown in FIGS. 11 and 12.

FIG. 11 shows one example of an etch mask pattern 1100 that can be used to form conductive lines into a pattern like that shown in FIG. 10A. Etch mask 1100 can include vertical opaque strips 1102 and vertical exposure strips 1104. Vertical exposure strips 1104 can form etch mask areas. For example, a resist layer can be exposed to energy (e.g., light, e-beam, etc.) to form etch masks. Those portions of the resist layer covered by opaque strips 1102 can be removed.

FIG. 12 shows how another etch mask pattern 1200 can be used to remove portions of conductive lines formed with mask 1100. Mask pattern 1200 can also include exposure area 1202 and horizontal opaque strips 1204. Horizontal opaque strips 1204 can prevent a resist layer to be exposed to energy, and thus not form an etch mask. This can enable conductive lines to be cut within cut areas CUT1 and CUT2.

By using a first mask 1100 to form conductive lines 702 to 714 in a first direction (e.g., vertical), and a second mask 1200 to make cut areas CUT1 and CUT2, the end corners of conductive lines in such cut areas can have well-defined edges. This is in contrast to approaches that would utilize a single mask. In the case of a single mask, due to proximity effects or the like, end portions of conductive lines in a cut area may be severely rounded or diminished and resulting transistors may not be properly formed.

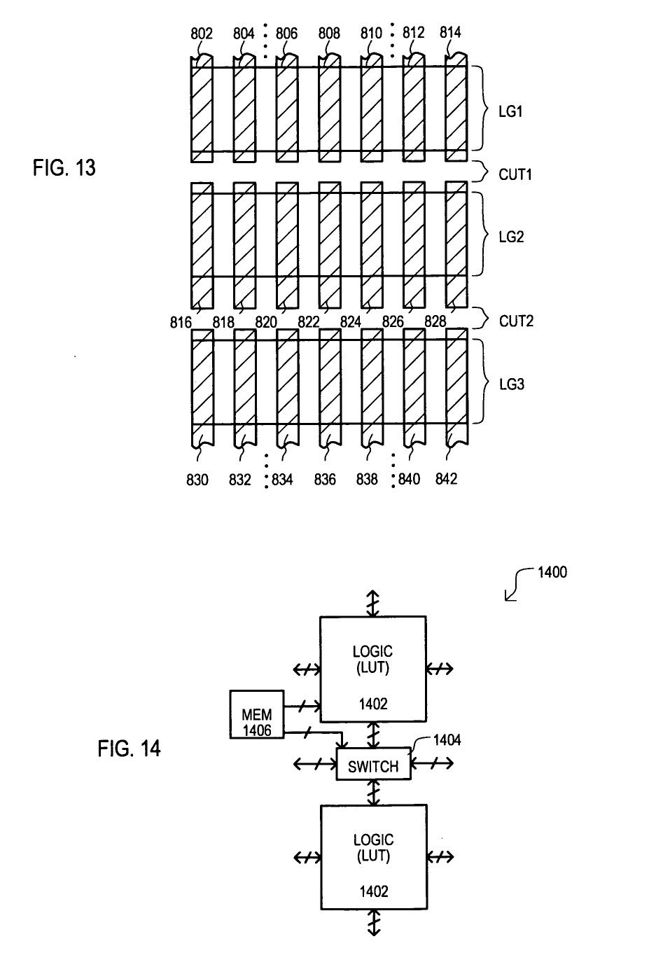

Referring now to FIG. 13, one example of a resulting conductive line pattern is shown in a top plan view. A first etch mask (e.g., formed with pattern 1100 of FIG. 11) can be used to form vertical edges of conductive lines 802 to 842 and a second mask (e.g., formed with pattern 1200 of FIG. 12) can be used to form horizontal edges of conductive lines 802 to 842. By using two masks to form orthogonal edges, rounded edges at small line widths (i.e. 65 nm and less) may be reduced. Furthermore, because the masks form orthogonal edges, mask alignment may be less critical.

Of course, the above etch patterns would be opposite from one another in the case of a positive resist.

The above embodiments can form various types of logic and other circuits with advantageously uniform pattern density. One of the many possible types of circuits that can be formed is shown in FIG. 14.

FIG. 14 shows a portion of a field programmable gate array (FPGA) 1400. FPGA 1400 can include a number of logic sections 1402 connected to one another by switch circuits 1404. Logic sections 1402 and switch circuits 1404 can be controlled according to configuration data provided by a memory section 1406.

A memory section 1406 may include static random access memory (SRAM) cells 1406 having a relatively high feature density. Similarly, a logic section 1402, which may include standard logic cells and/or look-up tables (LUTs) may have a high density, and in particular may include series connected transistors. Conventionally, a switching section 1404 may be composed of single switching devices, and hence can be less dense. However, by incorporating transistors like those of the above embodiments, feature density at a gate level can be made more uniform than conventional approaches, thus greatly reducing or eliminating adverse effects, such as “dishing”, that can arise from non-uniform density of features.

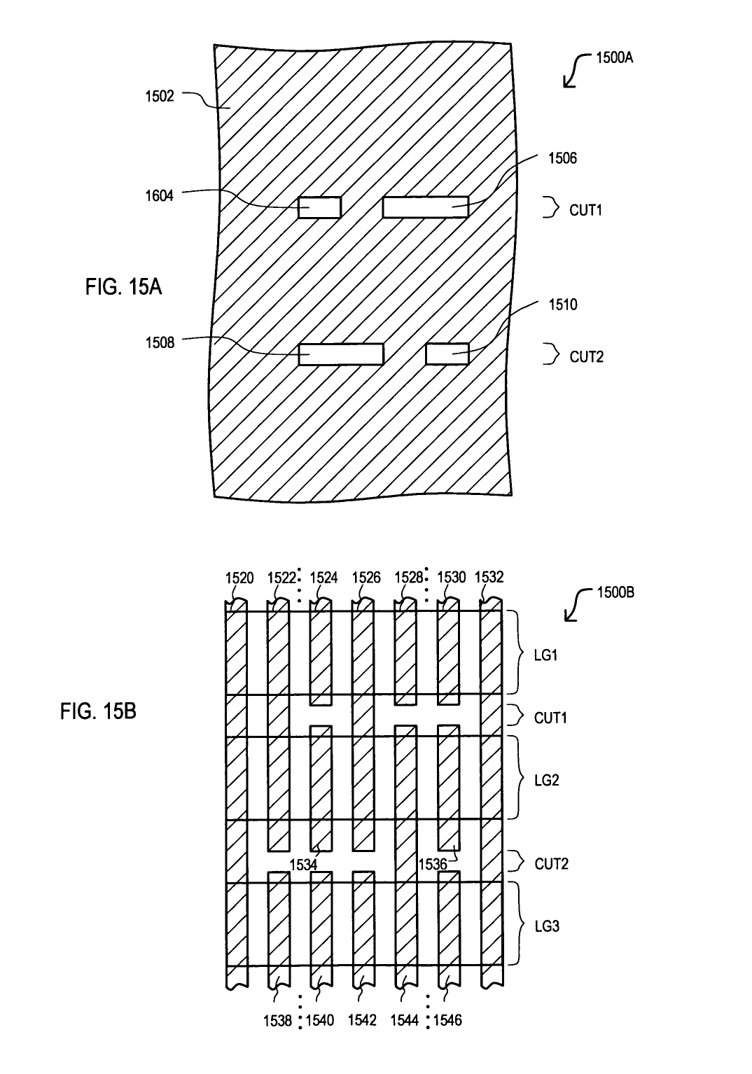

FIG. 15A shows how another etch mask pattern 1500A can be used to remove portions of conductive lines formed with mask 1100. Mask pattern 1500A can also include exposure area 1502 and horizontal opaque strips 1504 to 1510. Horizontal opaque strips 1504 to 1510 can prevent a resist layer from being exposed to energy, and thus not form an etch mask. This can enable selective conductive lines (such as conductive lines 702 to 714 in FIG. 10A) to be cut within cut areas CUT1 and CUT2.

By using a first mask 1100 to form conductive lines 702 to 714 in a first direction (e.g., vertical), and a second mask 1500A to make cut areas CUT1 and CUT2, the end corners of conductive lines in such cut areas can have well-defined edges. This is in contrast to approaches that would utilize a single mask. In the case of a single mask, due to proximity effects or the like, end portions of conductive lines in a cut area may be severely rounded or diminished and resulting transistors may not be properly formed.

Referring now to FIG. 15B, one example of a resulting conductive line pattern is shown in a top plan view. A first etch mask (e.g., formed with pattern 1100 of FIG. 11) can be used to form vertical edges of conductive lines 1520 to 1546 and a second mask (e.g., formed with pattern 1500A of FIG. 15A) can be used to form horizontal edges of conductive lines 1520 to 1546. By using two masks to form orthogonal edges, rounded edges at small line widths (e.g., 65 nm and less) may be reduced. Furthermore, because the masks form orthogonal edges, mask alignment may be less critical. As shown in FIG. 15B, conductive lines 1520 and 1532 may remain intact in the cut regions (CUT1 and CUT2) and be commonly connected between logic gates (LG1 to LG3). Conductive line 1522 may remain intact in the cut region CUT1 and be commonly connected between logic gates (LG1 and LG2). Conductive line 1544 may remain intact in the cut region CUT2 and be commonly connected between logic gates (LG2 and LG3). Conductive line 1520 may be source/drain connection, such as a power supply voltage, as just one example. Conductive lines 1522 and 1544 may be common source drain connections or control gate connections as just another example. Conductive line 1532 may be a well connection as just one example.

It should be noted that conductive lines (1520, 1522, 1532, and 1544) may be connecting transistors between transistor regions (LG1 to LG3) having different conductivity types. Thus, conductive lines (1520, 1522, 1532, and 1544) may include regions of opposite conductivity type dopants. However, by creating a metal silicide layer on the top surface of conductive lines (1520, 1522, 1532, and 1544), which may include polysilicon, any p-n junctions formed may be electrically shunted by the silicide (i.e. polycide) layer, or the like.

Of course, the above etch patterns would be opposite from one another in the case of a positive resist.

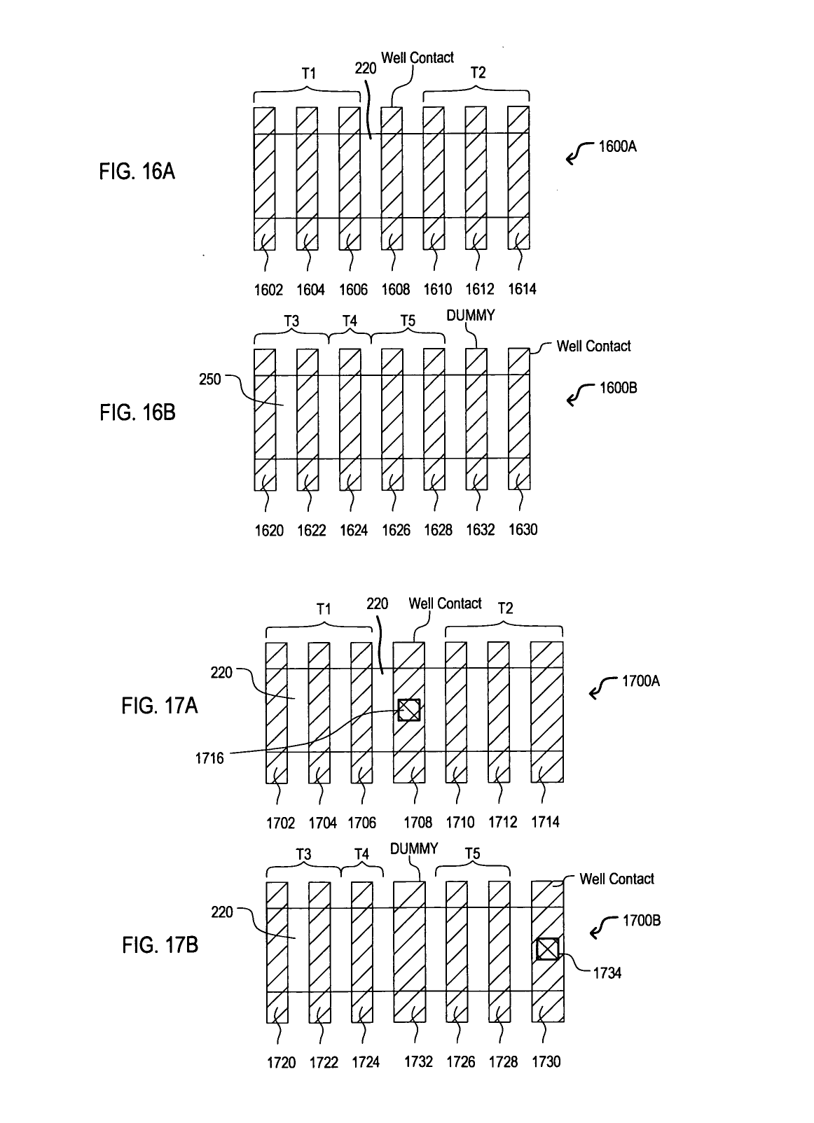

While the above embodiment have shown arrangements in which all first level conductive lines can be connected to separately operating terminals, in some embodiments, one or more conductive lines can be formed to present a uniformly dense pattern, and not be connected to any higher conductive layers. Such conductive lines can be considered “dummy” conductive lines. Examples of such arrangements are shown in FIGS. 16A and 16B.

Referring to FIGS. 16A and 16B, top plan views of transistor structures according to an embodiment used in various logic gates are illustrated having essentially uniform gate pattern densities. FIG. 16A is a top plan view of a single transistor structure 1600A that may be used in an inverter circuit, for example. FIG. 16B is a top plan view of a series transistor structure of four transistors that can be used in a three input NAND circuit, for example, and is given the general reference character 1600B.

Typically, the two single transistor structure 1600A can include seven conductive lines (1602 to 1614) including source, gates and drains for each transistor, along with a well contact between the transistors. In contrast, series transistor structure 1600B would only need six conductive lines (1620 to 1630) to operate. However, to provide a pattern density that matches that of FIG. 16A, a dummy conductive line 1632 may be added. In this way, an essentially uniform pattern density may be assured. It is noted that dummy conductive layer 1632 may be formed over a source/drain junction of an IGFET or a JFET, as just two examples, without having significant adverse affects on the operation of a series transistor structure 1600B. As noted above, a dummy conductive layer 1632 may have no connection other than the connection to the source/drain and may not provide any electrical benefits other than perhaps providing out diffusion for forming the source/drain. In other words, dummy conductive layer 1632 may only serve to provide the essentially uniform pattern density characteristics to improve manufacturability.

While the above embodiments have shown arrangements in which conductive lines are of uniform width, such an arrangement should not be construed as limiting to the invention. Alternate embodiments can provide uniform density with repeating line patterns that are not uniform in width. Examples of such embodiments will now be described with reference to FIGS. 17A and 17B.

Referring to FIGS. 17A and 17B, top plan views of transistor structures according to an embodiment used in various logic gates are illustrated having essentially repeated pattern densities. FIG. 17A is a top plan view of a single transistor structure 1700A that may be used in an inverter circuit, for example. FIG. 17B is a top plan view of a series transistor structure of four transistors that can be used in a three input NAND circuit, for example, and is given the general reference character 1700B.

The single transistor structure of FIG. 17A may include conductive lines 1702 to 1714. Conductive line 1708 which may form a source/drain connection to transistor T1 may have a contact 1716 formed thereon to provide an electrical connection to an upper conductive layer, for example, a metal layer formed above the polysilicon layer comprising conductive lines 1702 to 1714. Such a wider conductive line may make contact formation to such a line easier to accomplish. As but one example, conductive line 1708 can be larger than the minimum size contact size, preferably larger by an amount equal to or greater than a maximum contact misalignment value. In very particular example, a minimum contact size may be 65 nm, and a conductive line 1708 may have a width of about 75 nm.

Series transistor structure 1700B may include conductive lines 1720 to 1730 to form three transistors in series including a conductive layer 1730 for a well contact. However, in order to provide the same number of conductive layers as single transistor structure 17A, a conductive line 1732 may be included as a dummy conductive line. Conductive line 1732 may essentially match the width of conductive layer 1708 of FIG. 17A in order to provide a repeated pattern density. Conductive line 1730 can be a well contact that provides a biasing voltage to a well region. Again, as one particular example, a conductive line 1730 may have a width of 75 nm.

Referring still to FIGS. 17A and 17B, it is noted that series transistor structure 1700B may have a conductive line 1734 that also forms a well contact. Such a conductive line may also be wider than other conductive lines (1720, 1722, 1724, 1726 and 1728). For example, conductive line 1734 may have the same width as conductive line 1730. In order to provide essentially repeated pattern density, conductive layer 1714 within single transistor structure 1700B that provides a source/drain connection to a transistor T2, can have essentially the same width as conductive layer 1730.

In this way, a pattern may repeat (i.e., have a pitch) to provide a uniform pattern density across varying circuit functions.

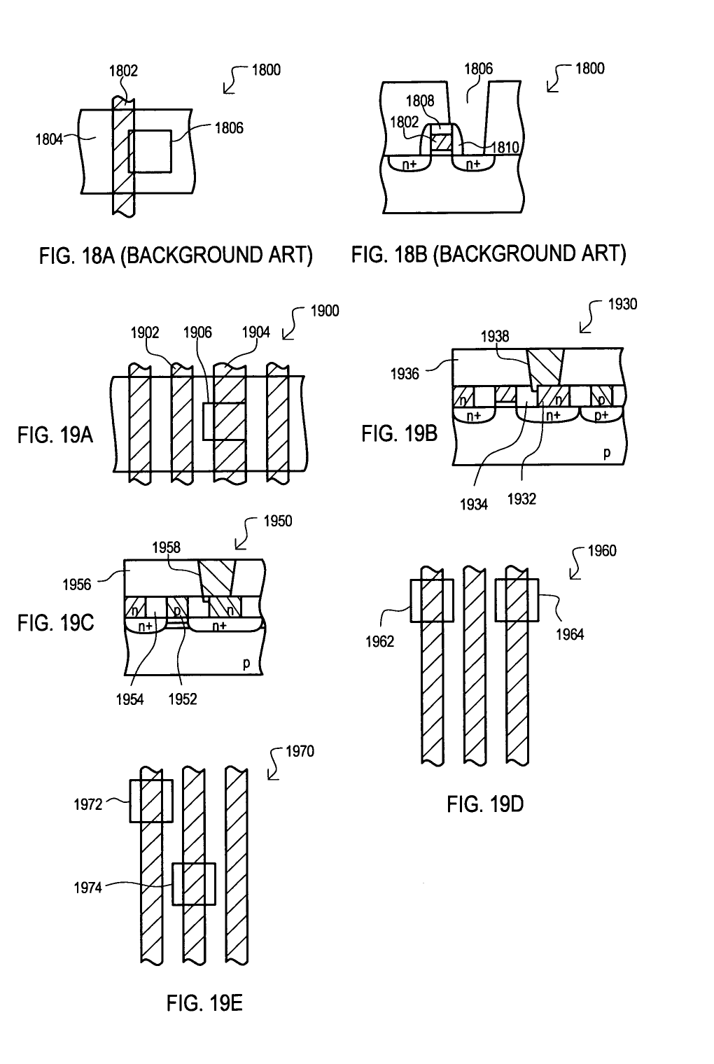

A conductive line structure as described in the various embodiments disclosed herein may provide for contact formation steps that are less constrained than conventional MOS manufacturing processes. To illustrate this, a conventional MOS source/drain contact formation will first be described with reference to FIGS. 18A and 18B. FIG. 18A shows a top plan view of a convention MOS source/drain contact. FIG. 18B shows the formation of a contact hole.

Referring now to FIG. 18A, a MOS structure 1800 can include a control gate 1802 formed over an active area 1804. A contact hole 1806 can be formed that overlaps control gate 1802 in order to form a “self-aligned” contact. As shown in FIG. 18B, in order to prevent a shorting of the control gate to the source/drain, a top insulator 1808 and sidewall 1810 can be formed on control gate 1802.

Referring now to FIGS. 19A to 19C, a contact formation step according to an embodiment will now be described.

Referring now to FIGS. 19A to 19C, a contact formation step according to an embodiment will now be described. FIG. 19A is a top plan view of a transistor structure showing the formation of a contact hole. FIG. 19B is a side cross sectional view showing the formation of a contact hole for an IGFET embodiment. FIG. 19B is a side cross sectional view showing the formation of a contact hole for a JFET embodiment.

Referring now to FIGS. 19B and 19C, after the conductive lines (e.g., 1932, 1952) are formed, an isolation layer (1934, 1954) can be formed over and between such lines. A planarization step, such as a CMP step, may then be performed to planarize the surface. A silicide layer, or the like can then be formed on top surfaces of the conductive lines (e.g., 1932, 1952). Subsequently, a second isolation layer (1936, 1956) may be formed.

A contact hole (1938, 1958) can then formed through second isolation layer (1936, 1956) to a desired conductive line, and a conductive material such as tungsten for example may be used to form a contact.

As shown in FIG. 19A, a contact hole 1906 to a source/drain conductive line 1904, need not overlap a gate conductive line 1902. Still further, referring back to FIGS. 19B and 19C, even if a contact hole (1938, 1958) is misaligned, isolation layer (1934, 1954) can prevent a substrate from being exposed. In addition, even if a substrate is exposed by a contact hole (1938, 1958), a device can still be operational. In particular, if a substrate is exposed so that a conductive contact material makes ohmic contact with the substrate, the contact structure can still provide a conductive connection to the source/drain region. In some embodiments, direct contact to a substrate may be preferable due to the reduced resistance of such an arrangement.

As a result, contact holes larger than a width of a control gate or source/drain structures can be implemented. Examples of adjacent contact spacing according to an embodiment are shown in FIGS. 19D and 19E. FIG. 19D illustrates three conductive patterned lines 1960 having contact holes 1962 and 1964. To add robustness to a manufacturing process (design for manufacture or DFM), contact holes adjacent to one another in a direction perpendicular to patterned lines 1960 can be placed, at the nearest, on every other conductive line. FIG. 19E shows three conductive patterned lines 1970 also having two contact holes 1972 and 1974. FIG. 19E shows how contacts between adjacent lines can be displaced in a direction parallel to the conductive lines 1970 in a DFM approach.

It is noted that the contact size and spacing of the approaches shown in FIGS. 19A to 19E may remove the need for the creation of “dog bone” contact landings for the conductive lines. That is, conventionally, in order to ensure a contact possesses sufficient contact area for a desired contact resistance, a conductive line can include a section that is wider than the rest of the line. However, in the above approaches, the need for such landings may be eliminated, as overlap of contact area may not affect device operation. In this way, contacts can be formed to IGFET and/or JFET devices.

While the embodiments of FIGS. 17A, 17B, and 19A to 19C have shown conductive lines having one particular variation in widths, it should be noted that the widths may vary even more significantly. For example, the width of one or more lines within a same repeating pattern may be up to three times that of other lines in the same pattern. By using dummy conductive lines, or aligning wide conductive lines from one logic gate with a source/drain conductive line, pattern densities may be repetitive and manufacturability may be improved.

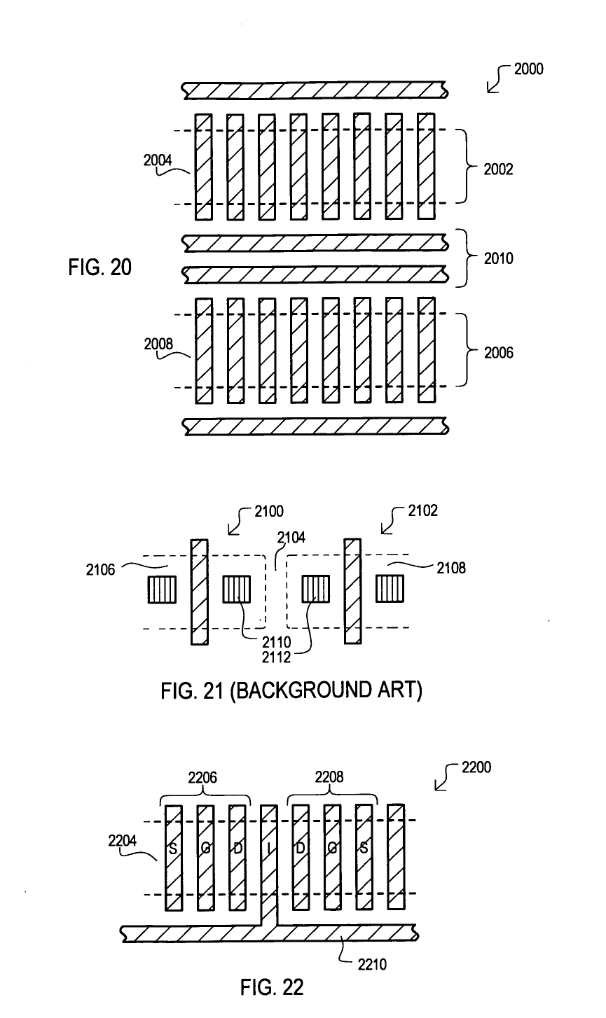

Referring now to FIG. 20, another example of a transistor structure is shown in a top plan view and designated by the general reference character 2000. A structure 2000 can include a first set of conductive lines 2002 arranged in parallel with one another in a first direction over a first active area 2004, and a second set of conductive lines 2006 arranged in parallel with one another in the first direction over a second active area 2008. In addition, structure 2000 can include a third set of conductive lines 2010 situated between the first and second sets (2002 and 2006). The third set 2010 can include lines arranged perpendicular to the first and second sets (2002 and 2006).

As will be described at a later point herein, the third set 2010 does not necessarily include contiguous lines, and can include breaks to allow connections between the first and second sets (2002 and 2006). In addition, portions of the third set 2010 can provide an electrical connection to lines of sets 2002 and/or 2006.

In this way, a structure 2000 can include sets of parallel lines arranged on one direction separated from one another by a third set of parallel lines arranged perpendicular to the other sets. Such an arrangement can provide for uniform density, while at the same time provide for various other features described below.

It is understood that the conductive lines of the first and second sets (2002 and 2006) can form gates, source contacts, drain contacts, for insulated gate field effect transistors (IGFETs) or junction FETs (JFETs), as described above. Such lines may also be “dummy” lines as noted above. Preferably, all conductive line sets (2002, 2006 and 2010) are formed from doped polysilicon in direct contact with a semiconductor substrate and forming JFET devices and interconnections between such devices.

To better understand features of the embodiments, a conventional MOS isolation structure will first be described with reference to FIG. 21. FIG. 21 is top plan view showing a first MOS transistor 2100 and second MOS transistor 2102 separated from one another by an isolation region 2104. Isolation region 2104 can insulate an active region 2106 of first MOS transistor 2100 from an active region 2108 of the second MOS transistor 2108. Such a conventional isolation structure is needed when a source/drain node 2110 of the first MOS transistor 2100 is expected to be driven to different potentials than a source/drain node 2112 of the second MOS transistor 2102. Isolation region 2104 is typically formed with a insulating material, such a silicon dioxide. Thus, the conventional approach incorporates structures formed from an insulation material to isolate one transistor from another.

Referring now to FIG. 22, one example of a structure having active isolation according to an embodiment is shown in a top plan view and designated by the reference character 2200. A structure 2200 can include a number of conductive lines arranged in parallel with one another over an active area 2204. Structure 2200 can include a first transistor 2206 and a second transistor 2208, each having a source contact line (S), a drain contact line (D) and a gate (G) formed by conductive lines. Preferably, transistors 2206 and 2208 can be JFETs with the conductive lines including patterned polysilicon.

In addition, the structure can include an isolation line (I) connected to an isolation supply line 2210. An isolation line (I) can form an isolation device operating in a deep cutoff mode through an isolating gate bias. Such a device can provide electrical isolation between first transistor 2206 and second transistor 2208. An isolation line (I) can be a patterned polysilicon line that makes contact with an active area. For an NJFET isolation device, such an isolating gate bias can be less than a low power supply voltage (e.g., less than zero volts).

In one particular arrangement, first and second transistors (2206 and 2208) can be n-channel JFETs, with sources that can be connected to a low power supply voltage (e.g., 0 volts), drains that can be selectively driven to a higher voltage (e.g., up to +0.5 volts), and a gate that can be driven between the low power supply voltage and a high voltage (e.g., between 0 and +0.5). However, isolation line (I) can be driven to a voltage lower than a low power supply voltage (e.g., −0.5 volts), placing the corresponding NJFET device into deep cutoff. In such an arrangement, a depletion region formed by an NJFET of isolation line (I), can electrically isolate first transistor 2206 from second transistor 2208.

Of course, while the above describes an arrangement in which NJFETs can be electrically isolated from one another, alternate arrangement can include PJFETs isolated from one another by driving a conductive line to a potential above a high power supply voltage, as but one example.

In this way, active devices can be formed adjacent to one another in the same active area, and be isolated from one another by the driving an intervening line to a predetermined potential, rather than by a structure formed from an insulating material.

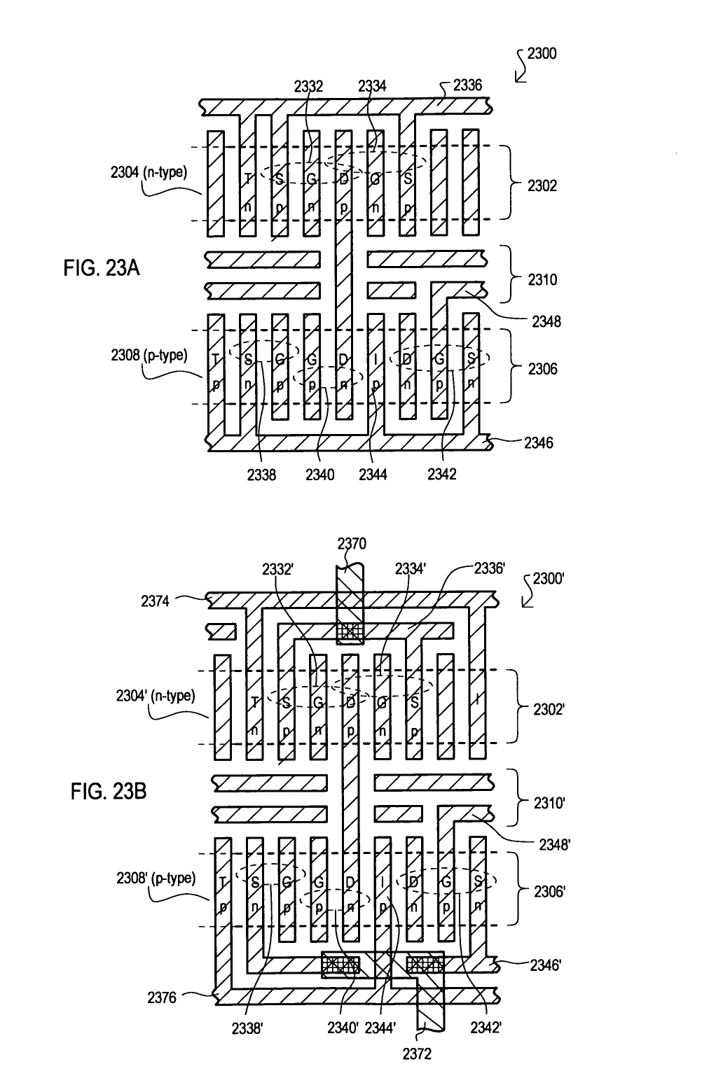

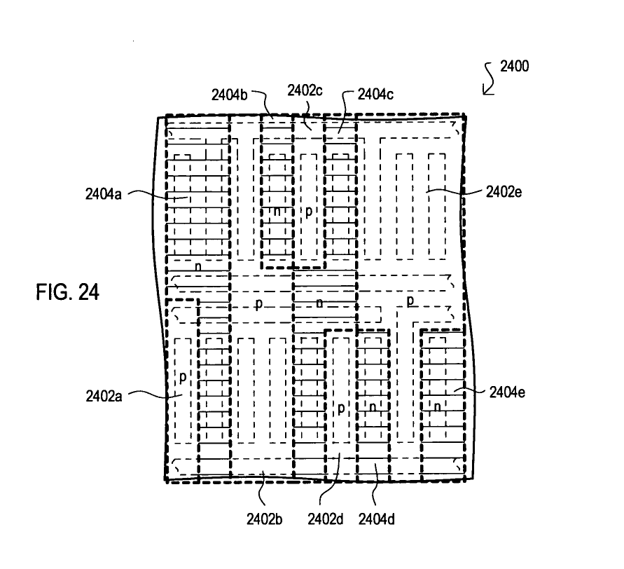

Structures like those above can allow for the formation of various circuits, including logic gates and the like. One particular example of such an arrangement is shown in FIGS. 23A, 23B and 24.

FIG. 23A is a top plan view of a structure, like that of FIG. 20, configured to form a two-input NAND gate and other circuits. FIG. 23A includes some of the same general items as FIG. 20. Such like items are referred to by the same reference character but with the first two digits being “23” instead of “20”.

Conductive line set 2302 can include a first p-channel JFET 2332, a second p-channel JFET 2334 formed on an n-type active region 2304. Transistors 2332 and 2334 can form parallel p-channel devices of a two-input NAND gate, and can have drain connections commonly connected to a supply line 2336 arranged perpendicular to conductive line set 2302. It is noted that while a supply line 2336 is preferably formed from the same layer as conductive line sets 2302, 2306 and 2310, in alternate arrangements, such a line can be formed by a substrate diffusion region or a conductive layer formed above the conductive line sets (2302, 2306 and 2310).

Second conductive line set 2306 can form portions of a first n-channel JFET 2338, a second n-channel JFET 2340, and a third n-channel JFET 2342. Transistors 2338 and 2340 can form series connected n-channel devices of the two-input NAND gate. A drain of transistor 2340 can be connected to shared drain of transistors 2332 and 2334 by a connection region 2346 that extends through third conductive line set 2310.

Conductive line set 2306 can also include isolation line 2344 that can provide electrical isolation between transistors 2340 and 2342. An isolation potential can be provided by way of isolation potential line 2346. As in the case of supply line 2336, isolation potential line 2336 is preferably formed from the same layer as conductive line sets 2302, 2306 and 2310. However, in alternate arrangements, such a line can be formed by a substrate diffusion region or a conductive layer formed above the conductive line sets (2302, 2306 and 2310).

The example of FIG. 23A also shows well “tap” structures (T) formed in both first and second conductive line sets (2302 and 2306). A tap (T) can provide a predetermined voltage to a well area, such as a high power supply voltage, or a low power supply voltage. A tap structure (T) can be doped to a same conductivity type as the substrate contacts.

As noted above, a third conductive line set 2310 can provide interconnection between devices formed in surrounding active areas (2304 and 2308) and other locations on an integrated circuit device. This is shown in FIG. 23A by a gate of transistor 2342 being connected to a conductive line within set 2310. It is understood that line 2348 of the third set can continue to another section of an integrated circuit.

Accordingly, it is understood that a third conductive line set 2310 can include discontinuities to allow connections between first and second conductive line sets (e.g., 2302 and 2306), as well as continuous connections such sets (e.g., gate connection of transistor 2342).

While the example of FIG. 23A shows an arrangement in which an isolation bias is the same as a JFET source bias, alternate embodiments may provide separate source biasing levels. One such example is shown in FIG. 23B.

FIG. 23B is a top plan view that includes the same general sections as FIG. 23A. Like sections are referred to by the same reference character but with an additional apostrophe “'”. FIG. 23B differs from that of FIG. 23A in that source of JFET devices can be biased differently from isolation lines and well taps. More particularly, in the case of the PJFET devices of first conductive line set 2302′, source lines (S) can be commonly connected by supply line 2336′, while a tap (T) and an isolation line (I) can be connected to well bias line 2374. Similarly, source lines (S) for second conductive line set 2306′ can be commonly connected to a supply line 2346′, while a tap (T) and an isolation line (I) can be connected to a well bias line 2376.

Supply line 2336′ can receive a power supply voltage via interconnect line 2370, which can be formed on a higher layer than the conductive line sets 2302′ and 2306′. In the same fashion, supply line 2346′ can receive a power supply voltage via interconnect line 2372, which can be formed on the same higher layer as interconnect line 2370.

In one very particular example, a supply line 2336′ can receive a high power supply voltage of +0.5 volts via interconnect line 2370, while a well supply line 2374 can receive a well bias voltage that is higher than +0.5 volts. In addition, a supply line 2346′ can receive a low power supply voltage of 0 volts via interconnect line 2372, while a well supply line 2376 can receive a well bias voltage that is lower than 0 volts.

In a JFET arrangement of the structures shown in FIGS. 23A and 23B, different conductive lines can be doped to different conductivity types to ensure proper operation. A particular conductivity type designation is shown by an “n” or “p” label.

Referring now to FIG. 24, a top plan view shows how sections of a conductive layer 2400 can be doped to “program” a particular gate configuration into sets of conductive lines. FIG. 24 shows how sections of a conductive layer, such as deposited polysilicon, can be doped to form an arrangement like that of FIG. 23A and/or 23B. FIG. 24 shows areas doped with p-type dopants 2402a to 2402e and areas doped with n-type dopants 2404a to 2404e can be created. Such areas can be formed according to ion implantation steps, as described above. FIG. 24 also shows general locations of conductive lines with dashed lines. Such lines can be patterned using photolithographic techniques, or the like, to arrive at the particular configuration shown in FIG. 23A.

It is noted that the minimum resolution for forming such p-type and n-type areas is considerably larger than a minimum gate length size. Further, such regions can advantageously accommodate overlap of differently doped regions, as such overlapping areas can be subsequently removed in the layer patterning step that forms the conductive lines.

In addition, where it is undesirable to create a p-n junction within a patterned polysilicon (or other semiconductor material) layer, a conductive layer can be formed over and in ohmic contact with the layer to provide a short circuit over such p-n junctions. As but one example, a silicide layer can serve as such a layer in the case of a patterned polysilicon layer.

In this way, a transistor structure can include multiple gate/contact regions for transistors with essentially uniform conductive lines arranged in parallel with one another. Such regions can be separated by interconnect regions with essentially uniform lines arranged perpendicular to the gate/contact regions. Different logic and/or other types of circuits can be formed by “programming” conductivities into gate/contact regions with a dopant-introducing step (e.g., ion implantation). Actual gates and contacts can then be patterned into an essentially uniform density structure. While the embodiments of FIGS. 20 and 22-24 have shown arrangements with uniform gate widths, it may be desirable to maintain essentially uniform feature density, while at the same time provide variable gate width. An example of such an arrangement is shown in FIG. 25.

Referring now to FIG. 25, one example of a structure having varying gate widths is shown in a top plan view and designated by the reference character 2500. A structure 2500 can include a number of conductive lines arranged in parallel with one another over an active area 2504′. Structure 2500 can include a first transistor 2506 and a second transistor 2508, each having a source contact line (S), a drain contact line (D) and a gate (G) formed with one of the conductive lines.

Active area 2504′ can include multiple regions of different size with respect to a gate width direction, and thus provide more than one gate length. In the example of FIG. 25, active area 2504′ can include one region 2504a having a first size in the direction of the parallel conductive lines, and another region 2504b having a different, smaller size in the direction of the parallel conductive lines. Transistor 2506 can be formed over the second area 2504b, and thus have one gate width. Transistor 2508 can be formed over the first area 2504a, and thus have a different gate width. However, while such transistors provide different operational widths, the structure maintains an essentially uniform density.

In this way, a transistor structure can provide a gate and source/drain contacts with an essentially uniform density that can accommodate variable gate widths.

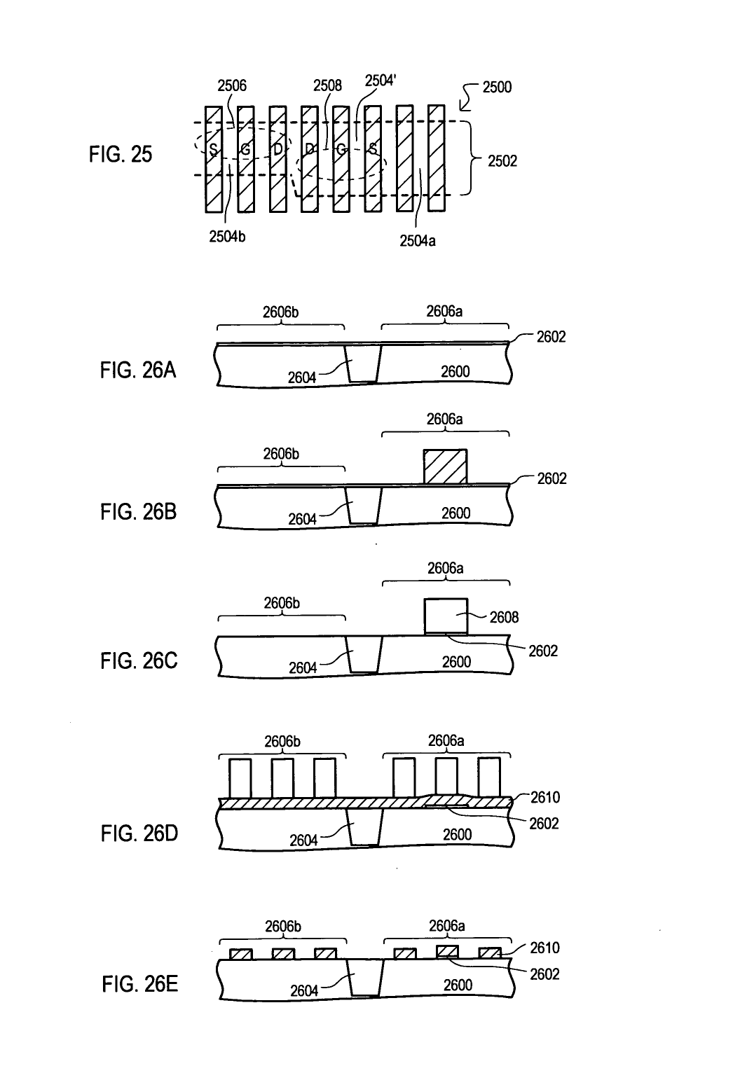

The above embodiments have described both IGFETs and JFETs separately. However, in some embodiments, both IGFETs and JFETs can be formed in the same integrated circuit substrate. One very particular example of such an approach is shown in FIGS. 26A to 26E.

FIG. 26A shows the formation of a gate insulating layer 2602 formed on a substrate 2600. It is understood that a substrate can include diffusion regions appropriate to the desired transistor device, and formed according to the above embodiments or well known techniques. Such regions can include any of: channel regions, back gate regions, source regions or drain regions. Substrate 2600 can include a first device region 2606a and second device region 2606b separated from one another in a direction parallel to a substrate surface by an isolation area 2604.

FIG. 26B shows the formation of a device type etch mask 2608 formed over a first device region 2606a. Such a mask can be formed according to conventional lithographic techniques.

FIG. 26C shows the removal of gate insulator layer 2602 in the second device region 2606b and selected sections of the first device region 2606a. Such a step can be conventional etching step suitable for the type of gate insulator and substrate material used. A device type etch mask 2608 can then be removed according to conventional techniques.

FIG. 26D shows the formation of a conductive layer 2610 over both first and second device regions 2606a and 2606b. It is noted that in a first device region 2606a, conductive layer 2610 can be formed over a gate insulator layer 2602 in locations of an IGFET gate. However, in a second device region 2606b, all of conductive layer 2610 can be formed in direct contact with a top surface of substrate 2600. A conductive layer 2610 can include a semiconductor material, preferably polysilicon or amorphous silicon. Further, such a layer can be selectively doped to different conductivity types (e.g., n-type or p-type) as described above. FIG. 26D also shows a line etch mask 2612 that can delineate lines patterns if essentially uniform density.

FIG. 26E shows a patterning step for forming conductive lines from conductive layer 2610. Such conductive lines can correspond to conductive line sets in the above embodiments, being essentially parallel to one another. In some embodiments, such lines are of uniform width, where width is parallel to the surface of substrate 2600 in FIG. 26E. In other embodiments, such widths can vary from one another.

In this way, both IGFET and JFET devices can be formed in the same integrated circuit device that include essentially uniform pattern density.

Reference in the description to “one embodiment” or “an embodiment” means that a particular feature, structure, or characteristic described in connection with the embodiment is included in at least one embodiment of the invention. The appearance of the phrase “in one embodiment” in various places in the specification do not necessarily all refer to the same embodiment. The term “to couple” or “electrically connect” as used herein may include both to directly and to indirectly connect through one or more intervening components.

Further it is understood that the embodiments of the invention may be practiced in the absence of an element or step not specifically disclosed. That is an inventive feature of the invention may include an elimination of an element.

While various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A semiconductor device, comprising:
a first circuit section including at least one transistor coupled to at least three conductive lines formed from a conductive layer, no more than one of the at least one of the three conductive lines forming a control terminal of the at least one transistor; and
a second circuit section including at least two transistors, each transistor having a control terminal formed by a conductive line formed from the same conductive layer; wherein
the three conductive lines of the first circuit section have essentially the same pitch pattern as the pitch pattern of the conductive lines of the second circuit section.

2. The semiconductor device of claim 1, wherein
the conductive layer comprises polysilicon layer.

3. The semiconductor device of claim 1, wherein:
the at least one transistor of the first circuit section comprises a field effect transistor (FET) having source coupled to one of the at least three conductive lines and a drain coupled to another of the at least three conductive lines; and
at least one transistor of the second circuit section comprises a FET having a source or drain coupled to a conductive line of the second circuit section.

4. The semiconductor device of claim 3, wherein:
the first circuit section includes at least a first transistor having a control gate formed by a first conductive line, at least a second transistor adjacent to the first transistor, having a control gate formed by a second conductive line, a third conductive line being situated between the first and second conductive lines;
the second circuit section includes at least a third transistor having a control gate formed by a fourth conductive line, at least a fourth transistor adjacent to the third transistor, having a control gate formed by a fifth conductive line, the fourth and fifth conductive lines being situated adjacent to one another with no other conductive lines formed between the fourth and fifth conductive lines.

5. The semiconductor of claim 1, wherein:
the at least one transistor of the first circuit section comprises a field effect transistor (FET) that does not share a source or drain region with an adjacent FET; and
the at least one transistor of the second circuit section comprises a plurality of FETs having source-drain paths arranged in series, each FET of the second circuit section sharing a source/drain region with an adjacent FET of the second circuit section.

6. The semiconductor device of claim 1, wherein:
the at least one transistor of the first circuit section is selected from the group consisting of an insulated gate field effect transistor (IGFET) and a junction field effect transistor (JFET).

7. The semiconductor device of claim 1, wherein:
the second circuit section includes a dummy conductive line that serves to provide essentially the pitch pattern of the first circuit.

8. The semiconductor device of claim 1, wherein:
the at least one transistor of the first circuit section comprises a first field effect transistor (FET), and the at least three conductive lines of the first circuit section include a first conductive line coupled to a source of the first FET, a second conductive line forming a control gate of the first FET, a third conductive line coupled to a drain of the first FET, the second conductive line being parallel with and adjacent to the first and third conductive lines; and
the at least one transistor of the second circuit section comprises a second FET and a third FET, the second circuit section including a fourth conductive line forming a control gate of the second FET, a fifth conductive line forming a control gate of the third FET, and a sixth conductive line coupled to a source or drain of the third FET, the fifth conductive line being parallel with and adjacent to the fourth and sixth third conductive lines.

9. The semiconductor device of claim 1, wherein:
the at least three conductive lines of the first circuit section include at least a first conductive line formed from a semiconductor material doped with impurities of a first conductivity type, and a second conductive line formed from the semiconductor material doped with impurities of a second conductivity type.

10. The semiconductor device of claim 9, wherein:
the at least one transistor of the first circuit section comprises a field effect transistor (FET) having source and drain regions of the first conductivity type, and the first conductive line is coupled to a source or drain of the FET and the second conductive line is coupled to a substrate region of the second conductivity type that includes the source and drain of the FET.

11. A semiconductor device comprising:
a first circuit section including a first plurality of conductive lines and at least a first field effect transistor (FET), a first of the conductive lines being coupled to a source or drain of a first FET, and least a second of the conductive lines forming a control gate of the first FET; and
a second circuit section including a second plurality of conductive lines and at least a second and third FET, at least two of the conductive lines forming control gates of the second and third FETs, at least a third of the conductive lines being coupled to a source or drain of the second FET;
wherein the first plurality of conductive lines and the second plurality of conductive lines are formed from the same conductive layer and have the same repeated pattern of line widths.

12. The semiconductor device of claim 11, wherein:
the first and second circuit sections are separated by a first cut region that disconnects selected ones of the first plurality of conductive lines from the second plurality of conductive lines.

13. The semiconductor device of claim 12, further including:
the first and second pluralities of conductive lines extend in a first direction, and the first cut region extends in a second direction essentially perpendicular to the first direction.

14. The semiconductor device of claim 11, wherein:
a third circuit section including a third plurality of conductive lines and at fourth FET, the third plurality of conductive lines being parallel to and formed from the same conductive layer as the first and second plurality of conductive lines.

15. The semiconductor device of claim 14, wherein:
the first and second circuit sections are separated by a first cut region that disconnects selected ones of the first plurality of conductive lines from the second plurality of conductive lines; and
the second and third circuit sections are separated by a second cut region that disconnects selected ones of the second plurality of conductive lines from the third plurality of conductive lines.

16. The semiconductor device of claim 11, wherein:
the first and second pluralities of conductive lines have first edges oriented in a first direction and second edges oriented in a second direction essentially perpendicular to the first direction, the first edges being defined by a first mask pattern and the second edges being defined by a second mask pattern.

17. The semiconductor device of claim 11, wherein:
the line widths of the first and second pluralities of conductive lines is no more than about 65 nm.

18. The semiconductor device of claim 11, wherein:
the first and second plurality of conductive lines comprise a doped polysilicon; and
the first, second and third FETs are selected from the group consisting of insulated gate field effect (IGFET) transistors and junction field effect (JFET) transistors.

19. The semiconductor device of claim 11, wherein:
the first plurality of conductive lines and the second plurality of conductive lines have the same line widths.

20. A semiconductor device, comprising:
a first plurality of conductive lines formed from a semiconductor layer that includes a first conductive line of a one conductivity type that forms a control gate of a first field effect transistor (FET) and a second conductive line of a different conductivity type coupled to a source or drain of the first FET;
a second plurality of conductive lines formed from the semiconductor layer that includes third and fourth conductive lines of one conductivity type that form control gates of second and third FETs, respectively, and a third conductive line coupled to a source or drain of the second FET; wherein
the first and second plurality of conductive lines are parallel to one another and have the essentially the same pitch pattern.

21. The semiconductor device of claim 20, wherein:
at least the first FET comprises a junction FET; and
the second and third FETs have a shared source/drain region.

22. A semiconductor device, comprising:
a first set of lines, patterned from a first deposited layer, each having a first width and arranged in parallel to one another in a first direction;
a second set of lines, patterned from the first deposited layer, each having the first width and arranged in parallel to one another in the first direction; and
a third set of lines, patterned from the first deposited layer, arranged between the first set of lines and second set of lines in a direction essentially perpendicular to the first and second sets of lines; wherein
at least two of the conductive lines of the first and second sets are in direct contact with a semiconductor substrate, without an intervening insulating layer.

23. The semiconductor device of claim 22, wherein:
the first deposited layer comprises silicon.

24. The semiconductor device of claim 22, wherein:
each line of the first set of the lines has essentially the same length;
each line of the second set of the lines has essentially the same length; and
third set of lines has the first width.

25. The semiconductor device of claim 22, wherein:
at least the first set of lines includes
a gate, source contact, and drain contact of a first junction field effect transistor (JFET) and a second JFET, the first and second JFETs operating within a first voltage range, and
an isolation line disposed between the first JFET and second JFET coupled to receive an isolation voltage outside of the first voltage range.

26. The semiconductor device of claim 22, wherein:
at least the first set of lines is formed over an active region formed in the substrate, the active region being defined by a surrounding insulating material and including at least a first and a second device size area, the first device size area being narrower in the first direction than the second device size area.

27. The semiconductor device of claim 22, wherein:
the first set of lines is formed over a first active area defined by a surrounding insulation material, and includes a gate, source contact, and drain contact of at least one junction field effect transistor (JFET); and
the second set of lines is formed over a second active area defined by a surrounding insulation material, and includes a gate, source contact, and drain contact of at least one insulated gate field effect transistor (IGFET); wherein
the gate, source contact, and drain contact of the at least one JFET device and the source contact and drain contact of the at least one IGFET device are in direct contact with the semiconductor substrate, without an intervening insulating layer, and the gate of the at least one IGFET device includes an intervening insulating layer between the gate and the substrate.

28. A method of forming a semiconductor device, comprising the steps of:
forming an electrode layer over a semiconductor substrate with at least a portion of the electrode layer in direct contact with a surface of the semiconductor substrate;
patterning the electrode layer into at least
a first set of lines, parallel to one another in a first direction and of essentially equal length, and formed over at least a first active area of the substrate,
a second set of lines, parallel to one another in the first direction and of essentially equal length, and formed over at least a second active area of the substrate, and
a third set of lines, parallel to one another in a second direction essentially perpendicular to the first direction.

29. The method of claim 28, further including:
before forming the electrode layer,
forming a gate insulating layer over the first device region and a second device region;
removing the gate insulating layer from the second device region;
selectively removing the gate insulating layer from portions of the first device region;
forming the electrode layer includes forming the electrode layer over the first and second device regions; and
patterning the electrode layer includes
forming a gate, source contact and drain contact of at least one junction field effect transistor (JFET), and
forming a gate, source contact and drain contact of at least one insulated gate field effect transistor (IGFET) in the second device region.

30. The method of claim 28, wherein:
patterning the electrode layer includes
forming discontinuities in the third set of lines, and
electrically connecting at least one of the lines of the first set of lines to at least one of the lines of the second set of lines by a line segment that passes within the discontinuities of the third set of lines.

31. The method of claim 28, wherein:
electrically connecting at least one of the lines of the first set of lines to at least one of line of a fourth set of lines with at least a portion of one of the lines of the third set of lines.

32. The method of claim 28, further including:
after forming an electrode layer and prior to patterning the electrode layer;
doping first sections of the electrode layer with at least a first conductivity type dopant, and
doping second sections of the electrode layer with at least a second conductivity type dopant.

33. The method of claim 32, wherein:
patterning the electrode layer includes
forming at least one junction field effect transistor (JFET) gate electrode from a first section of the electrode layer, and
forming at least one source/drain contact electrode for the JFET from a second section of the electrode layer.
